(19) United States
(12) Patent Application Publication
(10) Pub. No.: US 2006/0033507 A1
(43) Pub. Date: Feb. 16, 2006

(54) Capacitive detection system, particularly for a motor vehicle interior

(75) Inventors: Gerard Gaumel, Etampes (FR); Joaquim Da Silva, Orleans La Source (FR); Philippe Parbaud, La Ferte Saint Aubin (FR); Claude Launay, Champigny (FR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HITACHI COMPUTER PRODUCTS, Ardon (FR)

(21) Appl. No.: 10/541,720

(22) PCT Filed: Jan. 9, 2004
(86) PCT No.: PCT/FR04/00038

§ 371 Date: Jul. 8, 2005

(30) Foreign Application Priority Data
Jan. 10, 2003 (FR) 0300253

(51) Int. Cl. G01R 27/26

(52) U.S. Cl. 324/658

(57) ABSTRACT

A capacitive detection system comprising a capacitive sensor having a conductive electrode disposed to generate an electric field in a detection zone when the electrode is subjected to an electric potential, and an electronic control device connected at least to the first electrode. The first electrode of the capacitive sensor is disposed substantially entirely over a conductive screen connected to the control device.

The present invention relates to capacitive detection systems, in particular for motor vehicle interiors.

More particularly, the invention relates to a capacitive detection system comprising:
at least one capacitive sensor comprising at least one first conductive electrode disposed to generate an electric field at least in a detection zone when said first electrode is subjected to an electric potential; and
an electronic control device connected at least to the first electrode, said control device being adapted to impose an electric potential on the first electrode during at least a measurement period in which electric charge accumulates on the first electrode, in order subsequently, during a read period, to read the amount of electric charge that has accumulated on said first electrode.

Document WO-A-00/25098 describes an example of such a detection system, in which the capacitive sensors serve to detect the presence or the posture of a user sitting on a seat, e.g. for the purpose of controlling the operation of an inflatable airbag, etc.

That type of seat generally gives satisfaction, but presents the drawback that when the surface of the seat is damp (e.g. because a damp towel has been placed on the seat, or when a previous user had damp clothes with some of its water being absorbed by the seat, or indeed when water vapor has condensed on the seat), the signal delivered by the capacitive sensor can indicate the presence of a person even when there is no user sitting on the seat. The same problem can arise when a conductive object is placed on the seat.

The present invention seeks in particular to mitigate that drawback, specifically to improve the reliability of detection.

To this end, the invention provides a detection system of the kind in question, characterized in that it further comprises at least one conductive screen substantially covering the entire first electrode of the capacitive sensor on its side opposite from the detection zone, said first electrode being electrically insulated from said screen;

in that the control device is connected to said screen and is adapted to impose an electrical potential to the screen at least during the measurement period; and

in that the first electrode is connected to the control device by a first conductor provided with a shield adapted to prevent the conductor from delivering an electric field to the outside, the screen being in electrical contact with the shield of said conductor.

By means of these dispositions, it has been found experimentally that the signal given by the capacitive sensor enables detection to be performed reliably in the presence of moisture in the detection zone.

In embodiments of the invention, recourse may optionally also be had to one or more of the following dispositions:
the control device is adapted to bias the screen electrically relative to ground in the same direction as the first electrode during the measurement period;
the control device is adapted to impose the same electric potential to the screen as to the first electrode during the measurement period;
the control device is adapted to connect the screen to ground during the read period;
the capacitive sensor further comprises a second conductive electrode adjacent to the first electrode, the control device being connected to the second electrode and being adapted to impose an electric potential on said second electrode, at least during the measurement period;
the first and second electrodes of the capacitive sensor are disposed on the same conductive screen which is electrically insulated from said second electrode;
the first and second electrodes of the capacitive sensor are covered substantially entirely in the direction going away from the detection system by two juxtaposed conductive screens that are electrically insulated from said first and second electrodes, each of the first and second electrodes presenting a length that is distributed substantially equally over the two screens;
the two electrodes of the capacitive sensor are substantially parallel to each other and wound in a spiral;
a vehicle seat having at least a support surface for supporting a user, the capacitive sensor being disposed in the seat and the measurement zone being situated outside the seat in front of the support surface; and
the capacitive sensor is situated in the vicinity of the support surface of the seat.

Other characteristics and advantages of the invention appear from the following description of a plurality of embodiments, given as non-limiting examples and with reference to the accompanying drawings.

In the drawings:

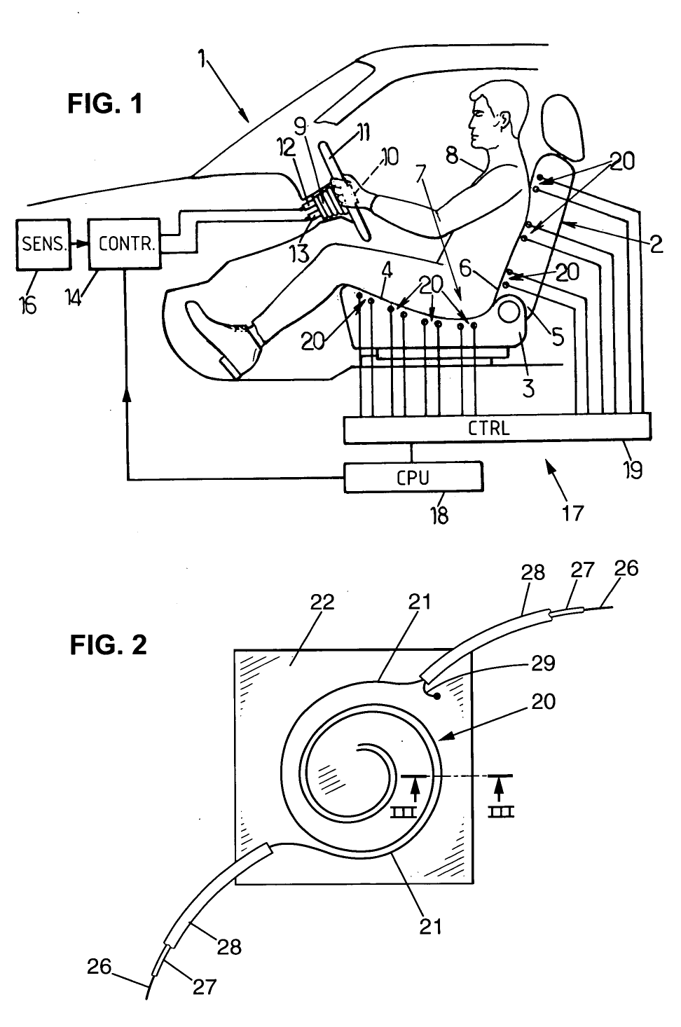

FIG. 1 is a diagrammatic view of a vehicle including a detection system constituting an embodiment of the invention;

FIG. 2 is a plan view of a capacitive sensor suitable for use in the FIG. 1 device;

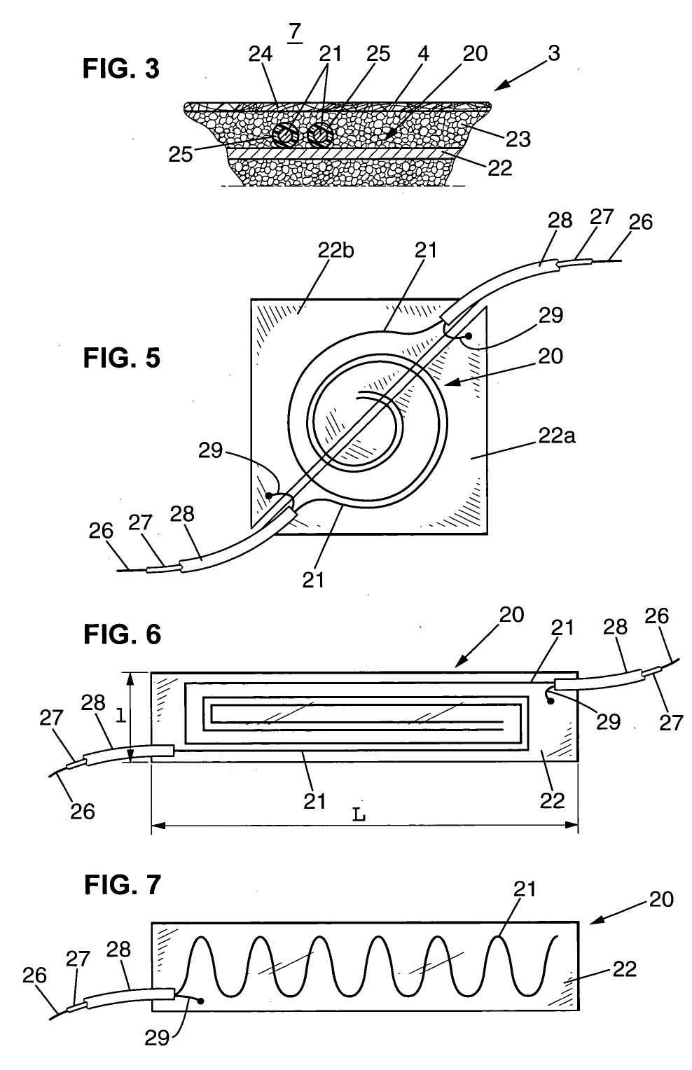

FIG. 3 is a detail view in section on line III-III of FIG. 1, showing the capacitive sensor when it is in place in the seat proper;

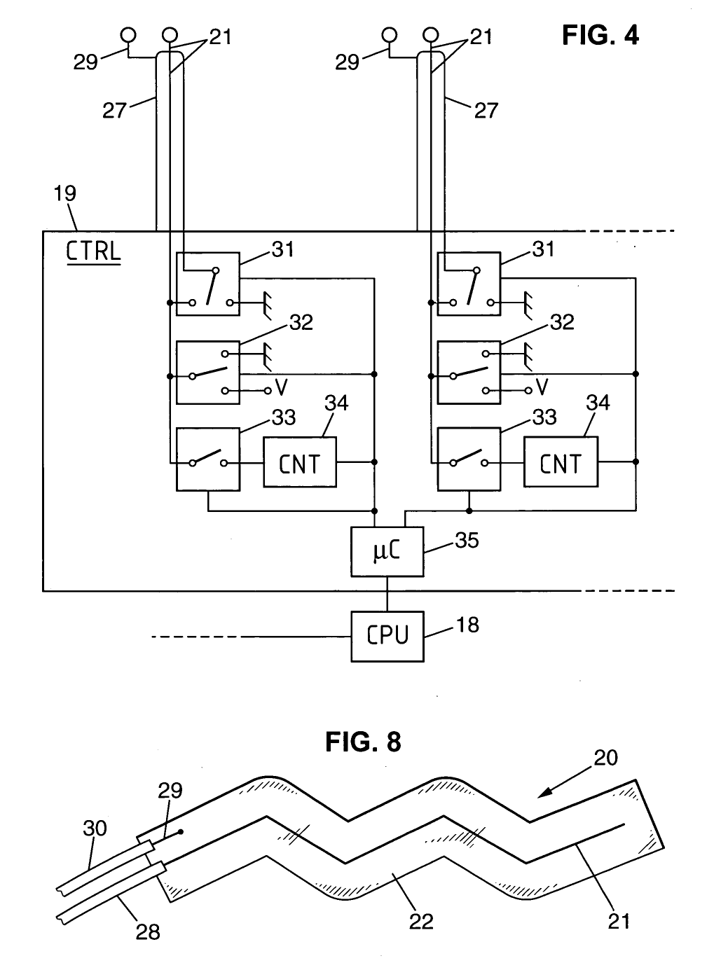

FIG. 4 is a fragmentary block diagram of the control circuit for the capacitive sensors of the FIG. 1 vehicle; and

FIGS. 5 to 8 are views similar to FIG. 2 showing four variants of the invention.

In the figures, the same references are used to designate elements that are identical or similar.

FIG. 1 shows a motor vehicle 1 having seats 2, one of which can be seen in FIG. 1, specifically the driver's seat. Naturally, the invention is equally applicable to other seats in the vehicle.

The seat 2 comprises a seat proper 3 presenting a top support surface 4, and a back 5 presenting a front support surface 6. The seat proper 3 and the back 5 define a receiving space 7 situated above the seat proper 2 and in front of the back 4, which space is for receiving a user 8 of the seat.

In order to protect the user 8 in the event of a road accident, the vehicle further includes one or more inflatable airbags, e.g. an inflatable airbag 9 placed in the central portion 10 of the vehicle steering wheel 11.

The airbag may present a plurality of modes of operation, for example two modes of operation depending on whether one or two explosive charges 12 and 13 are fired for generating different volumes of gas inside the airbag 9 when it is deployed.

The firing of one or the other of the two charges 12, 13 is performed under the control of a control device 14 such as an electronic microcontroller (CONTR.), and as a function of information coming in particular from:
an impact sensor 16 such as an accelerometer or the like (SENS.); and
a capacitive measurement device 17.

Specifically, the capacitive measurement device 17 may be of the type described in document WO-A-00/25098, it serves to perform capacitive measurement of the electric permittivity in the receiving space or detection zone 7 so as to determine the presence and/or the position or posture of the user 8 on the seat, and/or the user's weight.

By way of example, such a measurement device 17, which is not described again in detail herein, may comprise an electronic central processor unit 18 (CPU) such as a microcontroller or a microprocessor, connected to at least one control circuit itself connected to one or preferably a plurality of capacitive sensors 20, each comprising at least one electrode located in particular in the seat proper 3 and/or the back 5, in the vicinity of the support surface 4 and 6 against which the user 8 comes to bear.

As explained in the above-mentioned document WO-A-00/25098, the control circuit 19 generates an electric field in the space 7 by periodically applying a DC voltage V between the electrodes of each sensor 20. At the end of each measurement period, the control circuit 19 interrupts said DC voltage and measures the charge that has accumulated by the capacitive effect between the electrodes of each sensor 20, thus enabling the electric permittivity of the detection zone constituted by the receiving space 7 to be determined.

Since this permittivity varies as a function of the presence or non-presence of the user 8, and of the user's posture and weight, as taught in particular in document FR-A-2 813 054, the measurements performed by means of the various sensors serve to determine whether or not the user 8 is present, and/or to determine a position parameter for the occupant 8, and/or to determine a parameter associated with the user's weight.

These various parameters are taken into account by the control device 14 in determining which of the charges 12 and 13 it will trigger for the purpose of deploying the airbag 9 in the event of the sensor 16 detecting that the vehicle is being subjected to an impact.

The information coming from the detection device may also be used to govern the control of other members of the vehicle. Thus, this information may be taken into account, for example, in determining driving relationships for various actuator devices such as the vehicle suspension, air conditioning, the device for distributing braking, the device for trimming vehicle attitude, etc.

In order to prevent the measurements from the capacitive sensors 20 being disturbed by the presence of moisture or of conductive objects, in particular on the support surface 4, 6, at least some of the capacitive sensors 20 have their electrodes 21 disposed entirely on at least one conductive screen 22 that extends substantially parallel to the corresponding support surface 4, 6, as shown in FIGS. 2 and 3.

As can be seen in FIG. 3, the two electrodes 21 of the capacitive sensor 20 are disposed towards the outside of the seat relative to the conductive screen 22, the sensor 20 as a whole advantageously being integrated in the padding 23 of the portion of the seat where the sensor 20 is located (specifically the seat proper 3 in the example of FIG. 3), at a short distance beneath the outer decorative covering 24 of this portion of the seat.

The screen 22 may be constituted, for example, by a metal foil made of copper or of some other metal, that is a few hundredths or a few tenths of a millimeter thick, and the electrodes 21 are electrically insulated from said conductive foil, e.g. by means of insulating sheaths 25 surrounding said electrodes.

It should be observed that the electrodes 21 and the conductive screen 22 can also be made by silkscreen printing a conductive material onto insulating sheets, e.g. made of polyester or the like.

In the example of FIGS. 2 and 3, these two electrodes 21 of the sensors 20 are wound in a spiral, at a substantially constant distance apart from each other on a common conductive screen 22. In addition, each of these electrodes is connected to the control circuit 19 via two electrical conductors 26, each having a conductive shield 27 surrounding said electrical conductor 26 to prevent the conductor generating an electric field towards the outside of the seat when it has a voltage applied thereto.

The shield 27 is itself preferably surrounded by an insulating sheath 28, and the conductive screen 22 is connected to the shield 27 of at least one of the electrical conductors 26 via a link conductor 29.

In a variant, the electrical conductors 26 and each of their shields 27 could be made by silkscreen printing on insulating sheets of polyester or the like, each electrical conductor 26 then being in the form of a conductive line placed between two superposed conductive strips that are wider and that form the shield, said conductive strips being insulated from the conductive line by interposing insulating synthetic material.

Advantageously, during each measurement performed by means of the capacitive sensor 20, the control circuit 19 can impose a predetermined potential E to at least one of the two electrodes 21, to the corresponding electrical conductor 26, and where appropriate to the shield 27 of the two electrical conductors 26, such that the conductive screen 22 is always at the potential E whenever at least one of the two electrodes is at said potential E.

In one particular embodiment, the control device formed by the electronic CPU 18 and the control circuit 19 can be adapted to perform four measurements sequentially in any order:
a first measurement in which it measures the charge that has accumulated on one of the two electrodes 21, referred to as the “first electrode”, after the electric potential E has been imposed on said first electrode for a predetermined duration during which the second electrode is connected to ground;
a second measurement during which it measures the electric charge that has accumulated on the other electrode 21, referred to as the “second electrode”, after the electric potential E has been imposed on said second electrode during a predetermined duration during which the first electrode is connected to ground;
a third measurement in which it measures the electric charge accumulated on the first electrode 21 after imposing the potential E on both electrodes during a predetermined duration; and
a fourth measurement during which it measures the electric charge accumulated on the second electrode 21 after the potential E has been imposed on both electrodes for a predetermined duration (the predetermined durations during which the electric potential E is imposed on one or both electrodes are advantageously the same for all four measurements).

It has been found experimentally that in the presence of the conductive screen 22, combinations of those four measurements make it possible to distinguish between signals obtained with or without a user 8 sitting on the seat, even in the presence of considerable moisture or of a conductive object at the surface of the seat, for example in the presence of a wet towel placed on the seat.

In the embodiment described above, as is the other embodiments of the invention, the control device 19 may be of the type shown diagrammatically in FIG. 4, by way of example.

The control device 19 may comprise, for example, an internal microcontroller or microprocessor μC 35 which, for each electrode 21 controls:
a switch device 31 (a transistor or the like) adapted to connect the screen 22 either to ground or to the electrode 21;
a switch device 32 adapted to connect the electrode 21 either to ground or to a predetermined electric potential V; and
a switch device 33 adapted to connect the electrode 21 optionally to a counter device 34 (CNT) for measuring electric charge, which device can be read by the microcontroller 35.

Naturally, the capacitive sensor 20 may be different from that shown in FIGS. 2 and 3.

As shown in FIG. 5, the sensor 20 may comprise a plurality of conductive screens 22a, 22b, e.g. two conductive screens, that are electrically insulated from each other and each connected, for example, to the shield 27 of a respective one of the electrical conductors 26 of the electrodes, via electrical links 29. Under such circumstances, it is advantageous for each electrode 21 to have its length distributed substantially equally over both conductive screens 22a and 22b in a manner that is as symmetrical as possible between the two screens.

In this embodiment, the control circuit 19 can impose different electric potentials to the shield 27 of the two conductors during the measurement stages: for example, the electric potential of each conductor shield 27 may always be equal to potential of the corresponding electrical conductor.

Furthermore, as shown in FIG. 6, the electrodes 21 and 22 may be disposed other than in a rounded spiral: for example, the electrodes 21 may also be disposed in a spiral having right angles which may, for example, form an elongate strip of relatively narrow width e lying for example in the range 2 centimeters (cm) to 5 cm, and a length L lying, for example, in the range 10 cm to 30 cm, the length L of the sensor 20 being disposed either crosswise or lengthwise relative to the seat.

In the embodiment of FIG. 7, the capacitive sensor 20 may comprise a single electrode 21 disposed as in the preceding embodiments on the screen 22, being electrically insulated from the screen. The screen 22 is connected to the control device 17 so as to be put at the same (non-zero) electric potential as the electrode 21 during those measurement periods in which electric charge accumulates on said electrode, and connected to ground during read periods in which the control device reads the amount of electric charge that has accumulated on the electrode 21 during the read period. In this embodiment, it can be considered that the external medium (in particular a user 8, when present) forms a notional second electrode of the capacitive sensor.

In the embodiment of FIG. 8, the screen 22 is a conductive foil of zigzag shape following the shape of the conductive electrode. Furthermore, in this embodiment, the screen 22 is connected to the control circuit 19 via a separate wire 30 including the above-mentioned link conductor 29, which link conductor 29 may be connected to the circuit 19 as in the other embodiments (this disposition would also be possible in the other embodiments of the invention).

It should be observed that when the seat 2 has a plurality of capacitive sensors 20, these sensors may be of different types, and they need not all be implemented in accordance with the present invention.

Furthermore, it should also be observed that the detection system formed by at least one of the above-mentioned capacitive sensors and the control device can be used in applications other than in a vehicle seat. For example, the detection may be integrated in a vehicle dashboard, a vehicle roof, a steering wheel, a door, etc.

Finally, it should also be observed that in all embodiments of the invention, the electrode(s) 21 of the capacitive sensor need not be disposed against the conductive screen 22. The screen 22 could be disposed a few centimeters (e.g. 3 cm to 8 cm) beneath the electrode(s) 21, said screen then being separated from the electrode(s) by a thickness of synthetic foam belonging to the padding of the seat, for example. Under such circumstances, the conductive screen could optionally be formed by a resilient sheet on which the corresponding portion of the seat is suspended.

In all of the embodiments of the invention, the screen 22 may be constituted by any conductive member (a conducive foil, a conductive grid, a conductive mesh, a conductive fabric, a conductive foam, etc.):
that presents a surface area that is generally greater than that occupied by the electrode(s) 21;
that covers the electrode(s) 21 of the capacitive sensor substantially entirely on their side opposite from the detection zone 7; and
that is electrically insulated from the electrode(s) 21.

1. A capacitive detection system comprising:
at least one capacitive sensor comprising at least one first conductive electrode disposed to generate an electric field at least in a detection zone when said first electrode is subjected to an electric potential; and
an electronic control device connected at least to the first electrode, said control device being adapted to impose an electric potential on the first electrode during at least a measurement period in which electric charge accumulates on the first electrode, in order subsequently, during a read period, to read the amount of electric charge that has accumulated on said first electrode;
at least one conductive screen substantially covering the entire first electrode of the capacitive sensor on its side opposite from the detection zone, said first electrode being electrically insulated from said screen;
the control device being connected to said screen and is adapted to impose an electrical potential to the screen at least during the measurement period; and
the first electrode being connected to the control device by a first conductor provided with a shield adapted to prevent the conductor from delivering an electric field to the outside, the screen being in electrical contact with the shield of said conductor.

2. A detection system according to claim 1, in which the control device is adapted to bias the screen electrically relative to ground in the same direction as the first electrode during the measurement period.

3. A detection system according to claim 2, in which the control device is adapted to impose the same electric potential to the screen as to the first electrode during the measurement period.

4. A detection system according to claim 1, in which the control device is adapted to connect the screen to ground during the read period.

5. A detection system according to claim 1, in which the capacitive sensor further comprises a second conductive electrode adjacent to the first electrode, the control device being connected to the second electrode and being adapted to impose an electric potential on said second electrode, at least during the measurement period.

6. A detection system according to claim 5, in which the first and second electrodes of the capacitive sensor are disposed on the same conductive screen which is electrically insulated from said second electrode.

7. A detection system according to claim 4, in which the first and second electrodes of the capacitive sensor are covered substantially entirely in the direction going away from the detection system by two juxtaposed conductive screens that are electrically insulated from said first and second electrodes, each of the first and second electrodes presenting a length that is distributed substantially equally over the two screens.

8. A detection system according to claim 5, in which the two electrodes of the capacitive sensor are substantially parallel to each other and wound in a spiral.

9. A detection system according to claim 1, further comprising a vehicle seat having at least a support surface for supporting a user, the capacitive sensor being disposed in the seat and the measurement zone being situated outside the seat in front of the support surface.

10. A detection system according to claim 9, in which the capacitive sensor is situated in the vicinity of the support surface of the seat.
